(19) United States
(12) Patent Application Publication
(10) Pub. No.: US 2005/0230699 A1
(43) Pub. Date: Oct. 20, 2005

(54) Light-emitting device with improved optical efficiency

(76) Inventors: Bor-Jen Wu, Taipei (TW); Chien-An Chen, Hsin-Chuang City (TW); Mei-Hui Wu, Ming-Hsiung Hsiang (TW); Yuan-Hsiao Chang, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/104,463

(22) Filed: Apr. 13, 2005

(30) Foreign Application Priority Data
Apr. 16, 2004 (TW) 093110759

(51) Int. Cl. H01L 27/15

(52) U.S. Cl. 257/98

(57) ABSTRACT

A light-emitting device with improved optical efficiency is disclosed. A semiconductor substrate underlies active p-n junction layers, and has an internal scattering/reflecting surface near the bottom surface of the semiconductor substrate. Accordingly, the light originated at the active p-n junction layers is internally reflected from the internally curved reflecting surface, and substantially passes though the top surface of the semiconductor substrate.

### BACKGROUND OF THE INVENTION

1. Field of the Invention

The present invention discloses a light-emitting device with improved optical efficiency, in particular to a light-emitting diode having a substrate with a light scattering/reflecting surface.

2. Description of the Prior Art

FIGS. 1A and 1B are cross-sectional view and top view, respectively, of a conventional light-emitting diode (LED) respectively. As shown in FIG. 1A, an n-type layer 120, an undoped active layer 125, and a p-type layer 130 are sequentially grown on a substrate 110 by epitaxial growth process. When the structure is under forward biased current, photons are emitted due to the recombination of the minority carriers in the active layer. As shown in FIGS. 1A and 1B, a transparent electrode layer 140 is disposed on the p-type layer 130. Layer 140 firstly acts as an ohmic contact layer between the p-type layer 130 and a p-electrode (anode) 1501; secondly, it enhances the current spreading through the p-type layer 130. An n-electrode (cathode) 1502 is disposed on the exposed surface of the n-type layer 120, as preferably shown in FIG. 1B.

Part of the light generated from the active layer 125 passes through the transparent electrode layer 140, and is partly absorbed by layer 140. Another part of the light generated from the active layer 125 propagates toward the substrate 110. Some of the propagated light is emitted out of the LED from the bottom surface of the substrate 110 when the incident angle is less than the critical angle of total reflection, while light having incident angle greater than critical angle is repetitively reflected inside the substrate 110, as indicated by arrow 160 in FIG. 1A. The totally reflected light 160 is eventually absorbed inside the substrate 110. To increase the optical efficiency, the above mentioned are the two major loss mechanisms that the current invention aims to overcome.

### SUMMARY OF THE INVENTION

It is an object of the present invention to provide a light-emitting device with improved optical efficiency.

It is another object of the present invention to provide a light-emitting device having a substrate with an internal scattering/reflecting surface, such that the light originated at the active layer is substantially reflected or scattered from the substrate, and eventually emitted out of the light-emitting device, thereby increasing optical efficiency of the light-emitting device.

It is a further object of the present invention to provide a light-emitting device having an electrode layer or transparent conducting layer with openings formed therein, such that the light is minimally blocked or absorbed, thereby increasing optical efficiency of the light-emitting device.

In accordance with the present invention, a light-emitting device with improved optical efficiency is disclosed. A semiconductor substrate underlies active p-n junction layers, and has an internally scattering surface near the bottom surface of the semiconductor substrate. In one embodiment, the internal scattering/reflecting surface is formed, for example, by implanting process; in other embodiment, the bottom surface of the substrate is roughened or curved. Accordingly, the light originated at the active p-n junction layers is internally reflected from the internal scattering/reflecting surface, and substantially passes through the top surface of the semiconductor substrate, instead of internal total reflection as occurred in the conventional LEDs.

### BRIEF DESCRIPTION OF THE DRAWINGS

FIG. 1A is a cross-sectional view of a conventional light-emitting diode (LED);

FIG. 1B is a top view of the conventional LED of FIG. 1A, showing the arrangement of the p- and n-electrode;

FIG. 2 is a cross-sectional view illustrating the structure of an LED in accordance with one embodiment of the present invention;

FIG. 3A is a cross-sectional view illustrating the structure of an LED with a substrate having a rough bottom surface in accordance with the present invention;

FIG. 3B is a cross-sectional view illustrating the structure of an LED with a substrate having a semicircular geometric shape in accordance with the present invention;

FIG. 3C is a cross-sectional view illustrating the structure of an LED with a substrate having a triangular geometric shape in accordance with the present invention;

FIG. 3D is a cross-sectional view illustrating the structure of an LED with a substrate having a polyhedron geometric shape in accordance with the present invention;

FIG. 3E is a cross-sectional view illustrating the structure of an LED with a reflecting layer in accordance with the present invention;

FIG. 4A is a top view illustrating the structure of an LED in accordance with one embodiment of the present invention;

FIG. 4B is a top view illustrating the structure of an LED in accordance with another embodiment of the present invention;

FIG. 4C is a cross-sectional view of FIG. 4A, showing the structure of the LED;

FIG. 5 is a cross-sectional view illustrating the structure of an LED with a substrate having implanted regions in accordance with the present invention;

FIG. 6A is a cross-sectional view illustrating the structure of an LED with a substrate having a rough bottom surface in accordance with the present invention;

FIG. 6B is a cross-sectional view illustrating the structure of an LED with a substrate having a semicircular geometric shape in accordance with the present invention;

FIG. 6C is a cross-sectional view illustrating the structure of an LED with a substrate having a triangular geometric shape in accordance with the present invention;

FIG. 6D is a cross-sectional view illustrating the structure of an LED with a substrate having a polyhedron geometric shape in accordance with the present invention;

FIG. 6E is a cross-sectional view illustrating the structure of an LED with a reflecting layer in accordance with the present invention; and

FIG. 7 is a cross-sectional view illustrating the structure of an LED in accordance with an additional embodiment of the present invention.

### DESCRIPTION OF THE PREFERRED EMBODIMENT

It should be recognized that the present invention can be practiced in a wide range of other variations besides those explicitly described, and the scope of the present invention is expressly not limited except as specified in the accompanying claims.

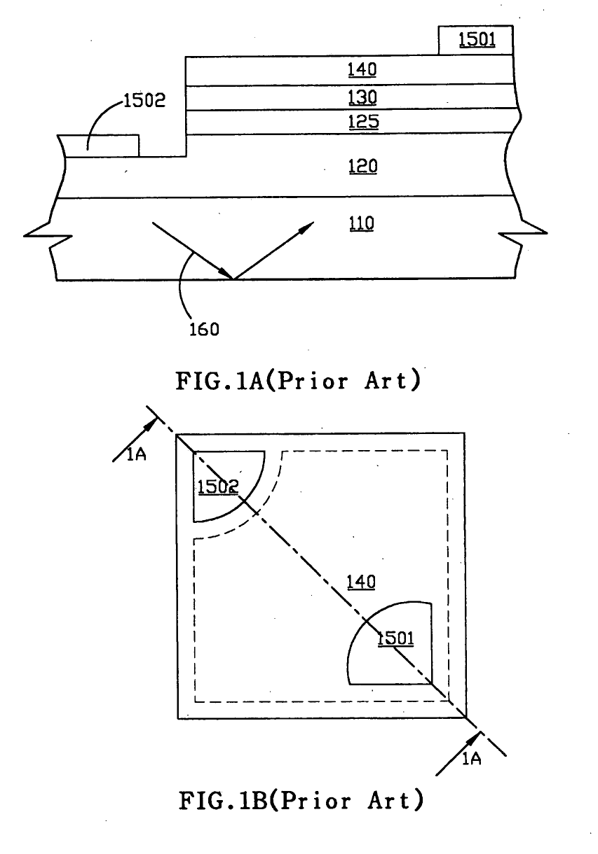

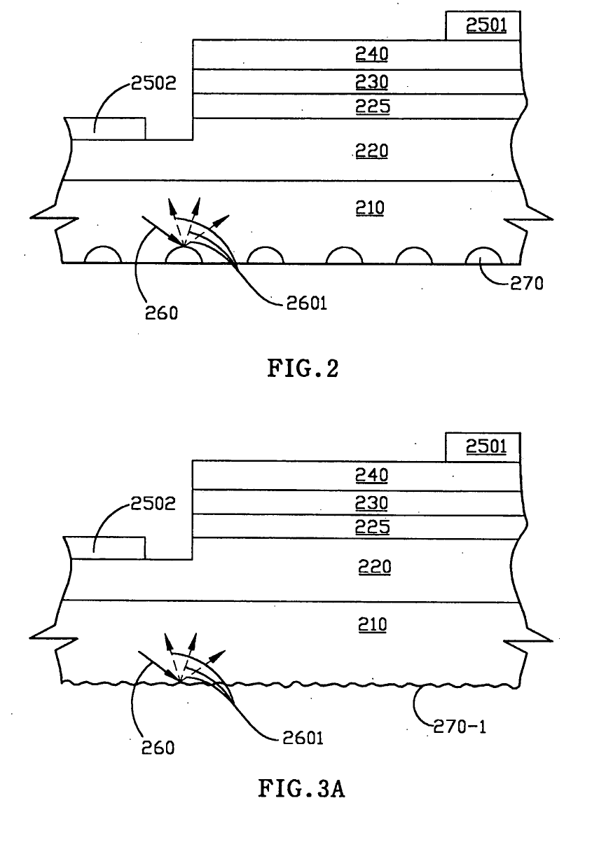

FIG. 2 is a cross-sectional view illustrating the structure of a light-emitting device, particularly a light-emitting diode (LED), in accordance with one embodiment of the present invention. This LED is structurally similar to that shown in FIG. 1A, where an n-type layer 220, an undoped active layer 225, and a p-type layer 230 are sequentially formed on a semiconductor substrate 210, for example, by an epitaxial growth process. The n-type layer 220, the undoped active layer 225, and the p-type layer 230 altogether also referred to as active p-n junction layers in this disclosure. A transparent electrode layer 240 is disposed on the p-type layer 230, and a p-electrode (anode) 2501 and an n-electrode (cathode) 2502 are disposed respectively on the transparent electrode layer 240 and the exposed surface of the n-type layer 220.

A number of regions 270 are defined and formed near the bottom surface of a substrate 210, such as sapphire. These defined regions 270 are formed, for example, by implanting ions different from the doped ions inside the substrate 210, if the substrate 210 is doped. Accordingly, these regions 270 have a refractive index different from that of the substrate 210 for that the material characteristic, composition, or density is changed. In operation, while the light 260 generated from the active layer 225 reaches the defined regions, it is scattered or reflected at a different angle, as indicated by arrows 2601, as compared to the conventional substrate 110 without the defined regions (FIG. 1A). The change of the path of the reflected light 2601 would increase the probability for the light to escape from the LED due to the change of incident angle.

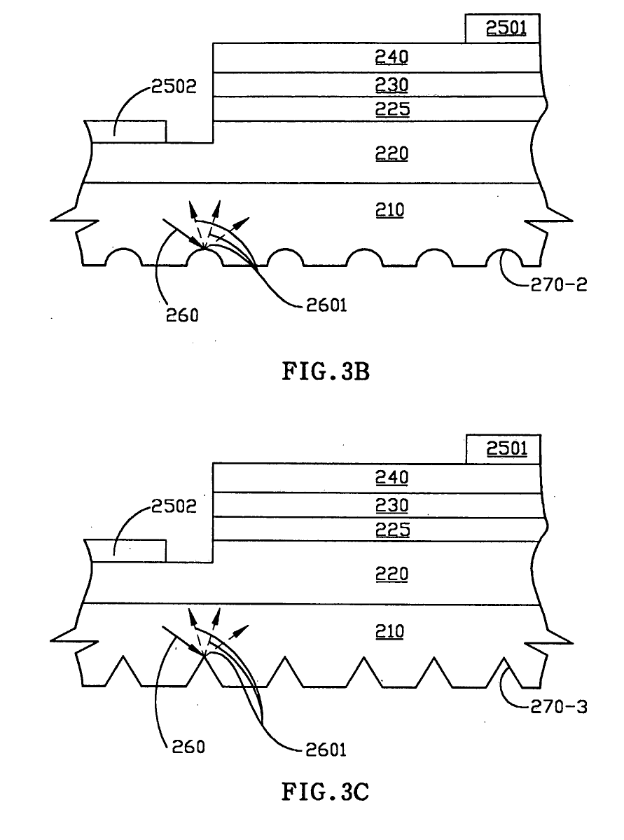

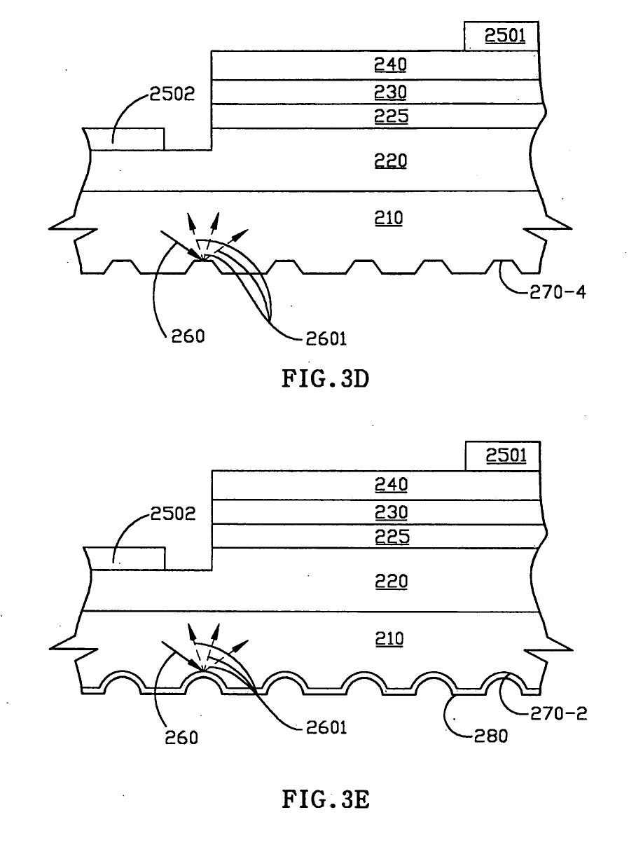

FIG. 3A illustrates the cross section of a light-emitting diode (LED) in accordance with another embodiment of the present invention. In this embodiment, the bottom surface of the substrate 210 is roughened, for example, by polishing technique, resulting in a randomly distributed rough surface 270-1. In operation, while the light 260 generated from the active layer 225 reaches the rough surface, it is scattered or reflected at a different angle of reflection, as indicated by arrows 2601, than the conventional substrate 110 with the smooth surface (FIG. 1A), therefore increasing the probability that the reflected light further passes through the n-type layer 220, the active layer 225, the p-type layer 230, the transparent electrode layer 240, and eventually emits out of the LED. Accordingly, an LED with improved optical efficiency is also attained.

Alternatively, the roughening processing of the bottom surface of the substrate 210 could be performed by other techniques, such as dry etching, wet etching, micromachining, micro replication, or laser techniques. Diverse geometric patterns or shapes in cross-sectional view, such as semicircular 270-2 (FIG. 3B), triangular 270-3 (FIG. 3C), or polyhedron 270-4 (FIG. 3D) could alternatively be used instead. As illustrated in FIG. 3E, a reflecting layer 280 could be further formed on the rough surface 270-1, 270-2, 270-3, or 270-4, resulting in a mirror surface, and further enhancing the reflection or scattering. The reflecting layer 280 could be made of materials such as sliver (Ag), platinum (Pt), molybdenum (Mo), Aluminum (Al), palladium (Pd), or a distributed Bragg reflector consisting of multiple dielectric layers, such as TiO₂/SiO₂.

As mentioned in the Background of the Invention of this disclosure, the light generated from the active layer 125/225 passes through the transparent electrode layer 140/240, and is somewhat blocked or absorbed by the transparent electrode layer 140/240. In order to overcome this drawback, the present invention discloses further embodiments, which are described as follows.

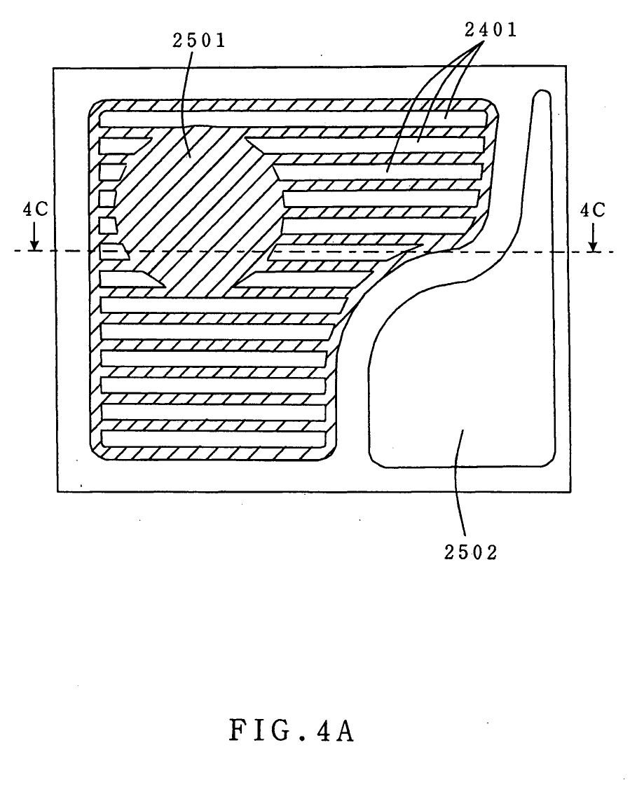

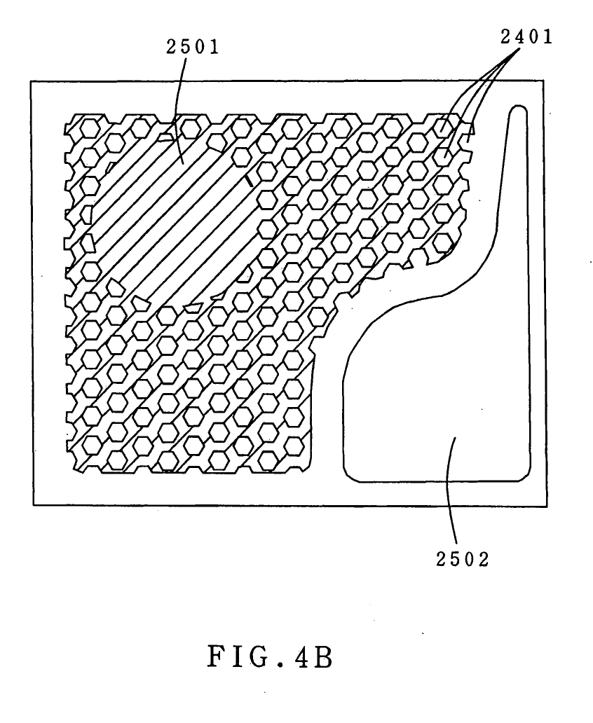

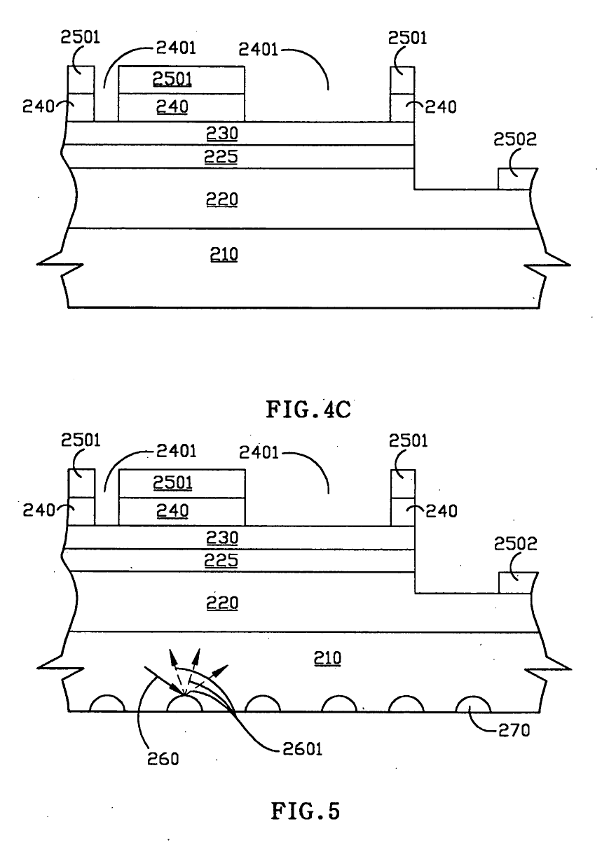

FIG. 4A is a top view illustrating the arrangement of the p-electrode (anode) 2501, the n-electrode (cathode) 2502, and the transparent electrode layer 240 in accordance with one embodiment of the present invention. FIG. 4B is a top view in accordance with another embodiment of the present invention. FIG. 4C is a cross-sectional view of FIG. 4A, showing the structure of the LED. Specifically, a number of openings 2401 are defined and formed in the transparent electrode layer 240, so that some of the light generated from the active layer 225 could be emitted out of the LED without being blocked, while the current through the LED could also be effectively spread by the transparent electrode layer 240. FIG. 4A shows elongated openings 2401 for instance, while FIG. 4B demonstrates hexagonal openings 2401. The implanted regions 270 as described in FIG. 2 are brought together with the specific transparent electrode layer 240 as described in FIGS. 4A-4C, resulting in a configuration of FIG. 5. The implanted regions 270 could be preferably arranged primarily under the openings 2401 to maximizing the optical efficiency. Although the bundle of the transparent electrode layer 240 and the p-electrode (anode) 2501 as shown in FIG. 4C and FIG. 5 possesses a two-layer structure, other structure having more than two layers is also possible.

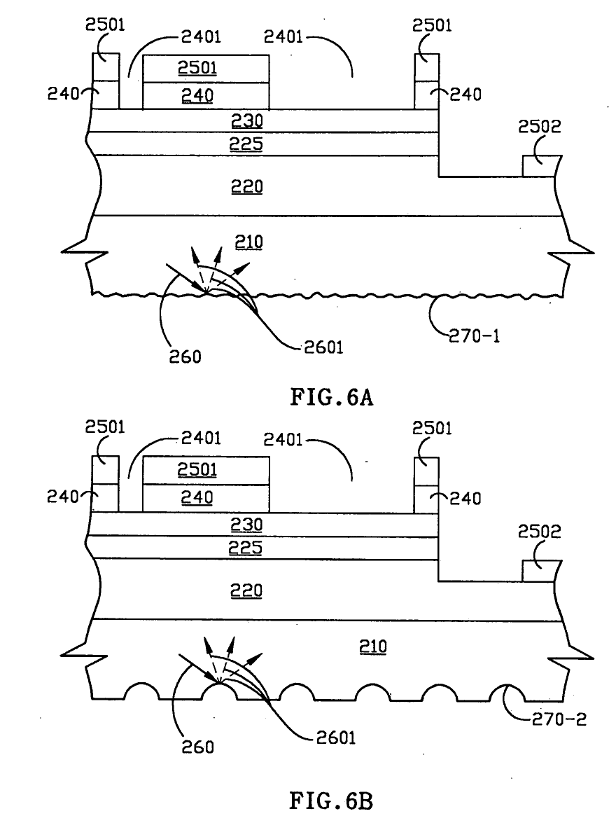

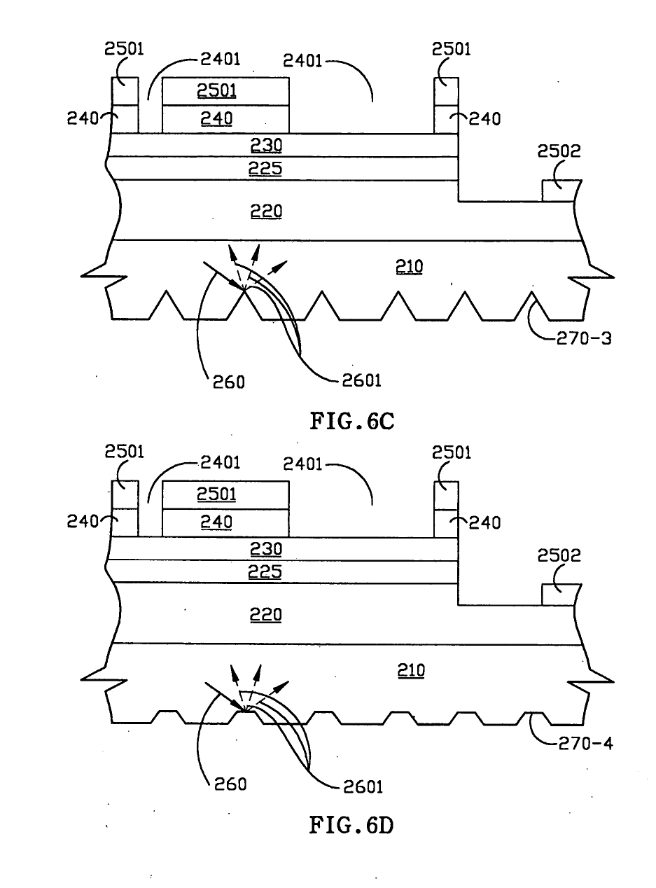

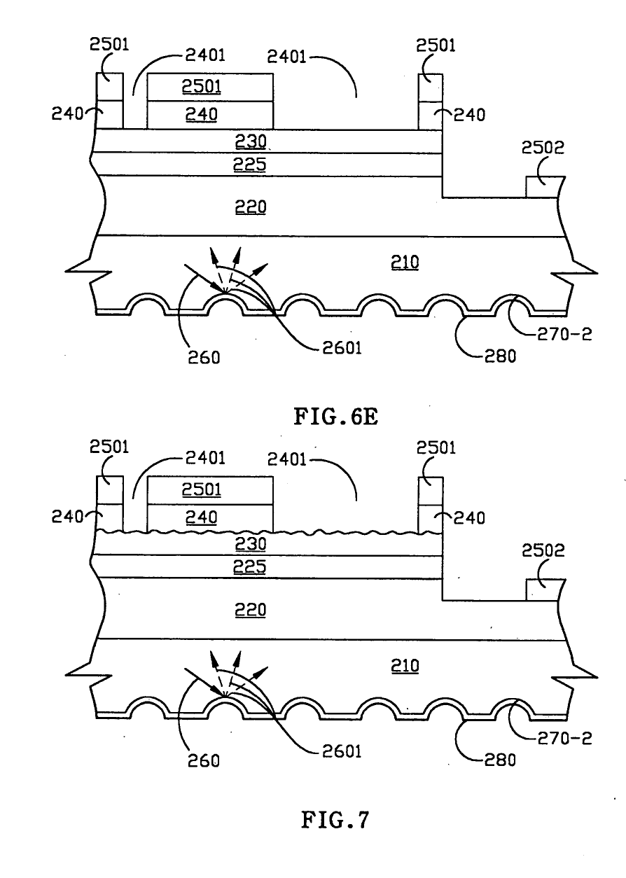

Referring to the embodiments of FIG. 6A-D, the bottom surface of the substrate 210 (FIG. 6A) is roughened as described accompanying FIG. 3A, or the bottom surface of the substrate 210 is curved with geometric patterns or shapes such as semicircular 270-2 (FIG. 6B), triangular 270-3 (FIG. 6C), or polyhedron 270-4 (FIG. 6D). As mentioned above, these geometric shapes could be preferably arranged primarily under the openings 2401 to maximizing the optical efficiency. Furthermore, a reflecting layer 280 could be further formed on the rough surface 270-1, 270-2, 270-3, or 270-4, to enhance the reflection or scattering as illustrated in FIG. 6E. The reflecting layer 280 is made of, for example, Ag, Pt, Mo, Al, Pd, or a distributed Bragg reflector consisting of multiple dielectric layers, such as TiO₂/SiO₂.

FIG. 7 illustrates a further embodiment which is similar to that of FIG. 6E, except that the top surface of the p-type layer 230 is roughened, which reduces the possibility that the light coming from the active layer 225 is reflected back. The rough surface of the p-type layer 230 could be made, for example, by changing the process parameters during the epitaxial process, or could be formed by an appropriate process after the epitaxial process. It is appreciated that rough surface of the p-type layer 230 shown in FIG. 7 could be adapted into other embodiments as discussed above.

The invention is not limited to the specific embodiments illustrated and described here, as it is obvious to those skilled in the art that various modifications may be made without departing from the spirit or scope of the general inventive concept as defined by the appended claims and their equivalents.

1. A light-emitting device, comprising:
a semiconductor substrate having a scattering/reflecting surface near the bottom surface of said semiconductor substrate;
active p-n junction layers overlying said semiconductor substrate for generating light; and
wherein the generated light internally reflected from said internally scattering/reflecting surface substantially passes through a top surface of said semiconductor surface.

2. The light-emitting device according to claim 1, further comprising an electrode layer overlying said active p-n junction layers.

3. The light-emitting device according to claim 2, wherein said electrode layer has a plurality of openings therein.

4. The light-emitting device according to claim 1, further comprising a reflecting layer formed on the bottom surface of said substrate, resulting in a mirror surface for reflecting the light.

5. The light-emitting device according to claim 1, wherein said active p-n junction layers have a rough top surface.

6. The light-emitting device according to claim 1, wherein said active p-n junction layers are epitaxially grown.

7. A light-emitting diode, comprising:
a semiconductor substrate having a plurality of regions defined and internally formed near a bottom surface of said semiconductor surface;
active p-n junction layers overlying said semiconductor substrate for generating light;
an electrode layer overlying said active p-n junction layers; and
wherein the generated light internally reflected from said defined regions substantially passes through a top surface of said semiconductor surface.

8. The light-emitting diode according to claim 7, wherein said defined regions are formed by implanting process.

9. The light-emitting diode according to claim 7, wherein said electrode layer has a plurality of openings therein.

10. The light-emitting diode according to claim 7, further comprising a reflecting layer formed on the bottom surface of said substrate, resulting in a mirror surface for reflecting the light.

11. The light-emitting diode according to claim 10, wherein said reflecting layer comprises material selected from the group consisting of sliver (Ag), platinum (Pt), molybdenum (Mo), Aluminum (Al), and palladium (Pd).

12. The light-emitting diode according to claim 7, wherein said active p-n junction layers have a rough top surface.

13. A light-emitting diode, comprising:
a semiconductor substrate having a curved or rough bottom surface;
active p-n junction layers overlying said semiconductor substrate for generating light;
an electrode layer overlying said active p-n junction layers; and
wherein the generated light internally reflected from said curved or rough bottom surface substantially passes through a top surface of said semiconductor surface.

14. The light-emitting diode according to claim 13, wherein said rough bottom surface is roughened by a polishing process.

15. The light-emitting diode according to claim 13, wherein said rough bottom surface is roughened by dry etching, wet etching, micromachining, micro replication, or laser technique.

16. The light-emitting diode according to claim 13, wherein said curved bottom surface has geometric pattern of semicircular, triangular, or polyhedron shape.

17. The light-emitting diode according to claim 13, wherein said electrode layer has a plurality of openings therein.

18. The light-emitting diode according to claim 13, further comprising a reflecting layer formed on the bottom surface of said substrate, resulting in a mirror surface for reflecting the light.

19. The light-emitting diode according to claim 18, wherein said reflecting layer comprises material selected from the group consisting of sliver (Ag), platinum (Pt), molybdenum (Mo), Aluminum (Al), and palladium (Pd).

20. The light-emitting diode according to claim 13, wherein said active p-n junction layers have a rough top surface.
